(19) United States
(12) Patent Application Publication
(10) Pub. No.: US 2007/0211439 A1
(43) Pub. Date: Sep. 13, 2007

(54) Electronic apparatus having drawer trays

(75) Inventor: Masato Shimizu, Tokyo (JP)

Correspondence Address: YOUNG & THOMPSON, 745 SOUTH 23RD STREET, 2ND FLOOR, ARLINGTON, VA, 22202, US

(73) Assignee: HIT CO., LTD., TOKYO (JP)

(21) Appl. No.: 11/369,952

(22) Filed: Mar. 8, 2006

(51) Int. Cl. H05K 5/00

(52) U.S. Cl. 361/724

(57) ABSTRACT

An electronic apparatus has plural circuit units, such as server components of a computer. A cabinet type apparatus case has plural outer cover panels. A front portion included in the outer cover panels is openable. Plural sliding drawer trays are arranged in a multi tier form, for containing respectively the server components, and are contained in the cabinet type case movably in a forward direction. Numerous inlets are formed in side cover panels among the outer cover panels, for air intake. Numerous vents are formed in front and rear cover panels among the outer cover panels, for air discharge. There are six fans for flowing in of air through the inlets, for blowing the air to the server components, and for venting the air through the vents, to cool the server components. A recess is formed in the drawer trays, opposed to the six fans, for passing the air.

### BACKGROUND OF THE INVENTION

1. Field of the Invention

The present invention relates to an electronic apparatus having drawer trays. More particularly, the present invention relates to an electronic apparatus in which drawer trays contain plural circuit units, and heat generated electrically can be dissipated effectively so as to ensure safe use of the circuit units.

2. Description Related to the Prior Art

In the field of electronic apparatuses, a rack type container is used to contain such an apparatus as a server computer. The container is constituted by a cabinet type case having a cabinet shape of which a front surface is open, and plural drawer trays in which a circuit unit such as a server component is mounted. The drawer trays are movable to slide freely into or out of the front surface of the cabinet type case. As example of electronic apparatus, the server computer or server apparatus provides information of various services to terminal devices connected in a network. A file server which makes user share files in the network, a print server for administering a printer in the network, and an electronic mail server for sending and receiving the electronic mail are unitized in the server apparatus. Each of server components of such a server is assembled in the drawer tray as circuit units.

If the server apparatus is used long in a continuous manner, its temperature is likely to rise excessively, because various electronic parts are mounted at a high density, including a central processing unit (CPU), a storage device, a power source device, and an I/O port. JP-A 11-204974, 2000-196273 and 2003-163480 disclose cooling of an electronic apparatus. A fan is incorporated in an upper portion, a lower portion, or each of both of those of a cabinet type case. An inlet of air is formed in the lower portion of the cabinet type case. A vent is formed in its upper portion. The fan is driven to introduce external cooling air into the cabinet type case through the inlet. The cooling air is discharged through the vent, in order to dissipate heat from the inside of the electronic apparatus.

The electronic apparatus according to those documents has the fan which causes the cooling air to flow upwards from the lower portion of the cabinet type case. There occurs a problem in non-uniform distribution in a flow rate of the cooling air. Some of circuit units or server components cannot receive the cooling air sufficiently. To solve such a problem, there have been suggestions for the electronic apparatus. Specifically, a direction of flow or the cooling air is adjusted by adding an air flow control panel or a unit for adjusting air flow. Also, a power source device is contained in a dead space which is disposed in an upper portion of the cabinet type case, suitably to modify the disposition of the circuit units or server components. However, such suggestions cause a rise in the manufacturing cost. The total of the structure of the electronic apparatus has become complicated, to lower operability of the electronic apparatus in the course of maintenance.

### SUMMARY OF THE INVENTION

In view of the foregoing problems, an object of the present invention is to provide an electronic apparatus in which drawer trays contain plural circuit units, and heat generated electrically can be dissipated effectively so as to ensure safe use of the circuit units.

In order to achieve the above and other objects and advantages of this invention, an electronic apparatus having plural circuit units is provided, in which a cabinet type apparatus case has plural openings and plural outer cover panels, wherein the plural openings are formed in respectively at least a front face and first and second side faces thereof, and the outer cover panels close the plural openings. Plural sliding drawer trays are arranged in a multi tier form, contained in the cabinet type case, movable in and out through a front opening included in the openings, wherein each of the drawer trays has a lower panel and a peripheral panel, each of the circuit units is secured to the lower panel, and contained therein. A vent is formed in at least one of the outer cover panels, for air discharge. An inlet is formed in a cover panel of the outer cover panels different from the vent, for intake of external air for cooling. There are at least one first to fourth fans for flowing in of air through the inlet, for blowing the air to the circuit units, and for venting the air through the vent, to cool the circuit units. The first and second fans are disposed on respectively the first and second side faces, and the third and fourth fans are disposed higher than the first and second fans respectively at a predetermined distance. At least one recess is formed in the drawer trays, opposed to at least one of the first to fourth fans.

The vent is formed in each of the front face and a rear face of the cabinet type case. The inlet is formed in each of the first and second side faces. The at least first to fourth fans are disposed between the first or second side face and the drawer trays.

Each of the circuit units includes a heat generating part mounted in a concentrated manner, and located close to one of the first to fourth fans.

The recess is formed in the peripheral panel.

The recess is formed in a portion of the peripheral panel positioned on one of the first and second side faces and a rear face of the cabinet type case.

The outer cover panels include a front cover panel, disposed on the front face, for closing one of the openings. A rear cover panel is disposed on a rear face of the cabinet type case, for closing one of the openings. First and second side cover panels are disposed on respectively the first and second side faces, for closing openings among the openings.

The cabinet type case and the first to fourth fans satisfy a condition of
L/3≦φ<L
where φ is an outer diameter of the first to fourth fans;
L is a length of a shorter side line of the side faces.

The plural drawer trays are constituted by first and second drawer tray stacks, and the second drawer tray stack is disposed beside the first drawer tray stack. Furthermore, plural guide supports are disposed on an inside of the cabinet type case, for guiding plural drawer trays movable in and out.

The vent is constituted by a first group of vents disposed in a rear face of the cabinet type case. A second group of vents are disposed in the front face, and having a total area of openness larger than a total area of openness of the first group of the vents.

The circuit units are server components.

The at least first to fourth fans are at least first to sixth fans, and the fifth and sixth fans are disposed higher than the third and fourth fans respectively at a predetermined distance.

In a preferred embodiment, an electronic apparatus having plural circuit units includes a cabinet type apparatus case, having plural outer panels, wherein a front portion included in the outer panels is openable. Plural sliding drawer trays are arranged in a multi tier form, for containing respectively the circuit units, the drawer trays being contained in the cabinet type case movably in a forward direction. An inlet is formed in at least one of the outer panels, for air intake. A vent is formed in at least one of the outer panels different from the outer panel where the inlet is disposed, for air discharge. There is at least one fan for flowing in of air through the inlet, for blowing the air to the circuit units, and for venting the air through the vent, to cool the circuit units. A recess is formed in the drawer trays, opposed to the at least one fan, for passing the air.

The at least one fan is opposed to the inlet and positioned inside the outer panels.

The outer panels include a front panel, a rear panel, and first and second side panels. The inlet is formed in each of the first and second side panels. The vent is formed in each of the front panel and the rear panel.

The at least one fan includes at least one first fan positioned on the first side panel, and at least one second fan positioned on the second side panel.

### BRIEF DESCRIPTION OF THE DRAWINGS

The above objects and advantages of the present invention will become more apparent from the following detailed description when read in connection with the accompanying drawings, in which:

FIG. 1 is an exploded perspective view illustrating a server apparatus;

FIG. 2 is a front elevation illustrating a state of a cabinet type apparatus case where drawer trays are removed;

FIG. 3 is a side elevation illustrating a state of fans viewed in the cabinet type case;

FIG. 4 is a perspective view illustrating one of the drawer trays and a server component;

FIG. 5 is a perspective view illustrating another preferred drawer tray and a server component.

### DETAILED DESCRIPTION OF THE PREFERRED EMBODIMENT(S) OF THE PRESENT INVENTION

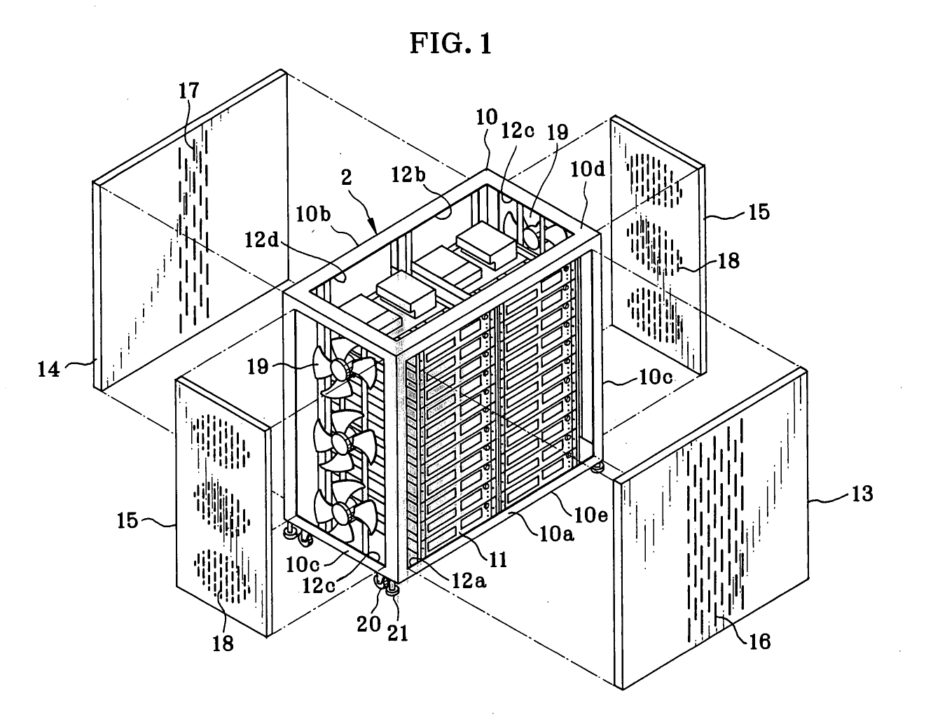

In FIG. 1, a server apparatus 2 or cluster of a computer, as electronic or electric apparatus, includes a cabinet type apparatus case 10 or housing of aluminum, and sliding drawer trays 11 of aluminum in a multi tier form. The number of the drawer trays 11 is 22, as their multi tier form has 11 tiers, and two stacks located beside one another. The cabinet type case 10 includes openings formed in case faces, and cover panels for closing the openings by fastening with screws or the like. A front opening 12a is formed in a front face 10a. A front cover panel 13 among outer cover panels closes the front opening 12a. A rear opening 12b is formed in a rear face 10b. A rear cover panel 14 among the outer cover panels closes the front opening 12a. A side opening 12c is formed in each of side faces 10c. Side cover panels 15 among the outer cover panels close the front opening 12a. An upper opening 12d is formed in an upper face 10d. An upper cover panel closes the front opening 12a. Vents 16 and 17 are formed through the front and rear cover panels 13 and 14. Inlets 18 are formed in the side cover panels 15.

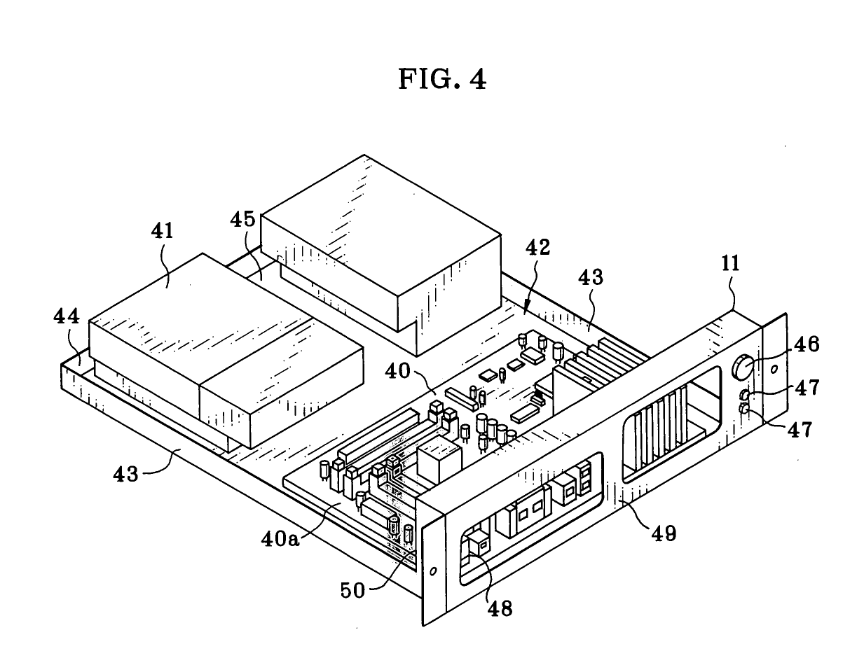

First to sixth fans 19 or blowers, which are at least four, are associated with the side faces 10c of the cabinet type case 10. On each of the side faces 10c are arranged three of the fans 19 in a vertical direction. The fans 19 introduce external gas or air through the inlets 18 of the side cover panels 15 into the cabinet type case 10. Server components 42 or cluster nodes as circuit units of FIG. 4 are disposed in the drawer trays 11, and cooled by the introduced cooling gas. The cooling gas is vented through the vents 16 in the front cover panel 13, and the vents 17 in the rear cover panel 14 to the outside. A power source pushbutton 46 is depressible to supply the server components 42 with power. There is an opening (not shown) formed in the front cover panel 13 for facilitating access to the power source pushbutton 46. The number of the vents 16 in the front cover panel 13 is greater than that in the rear cover panel 14, so as to increase an amount of vented cooling air in the forward direction. In other words, a total area of the openness of the vents 16 in the front cover panel 13 is larger than that in the rear cover panel 14.

A lower face 10e is included in the cabinet type case 10. Four caster wheels 20 are disposed on the lower face 10e, and rotatable to facilitate manual transport of the server apparatus 2. Four lower supports or legs 21 protrude from the lower face 10e for fixedly setting the cabinet type case 10 in an installed state. The lower supports 21 are adjustable finely to change a height of the cabinet type case 10. A hub (not shown) is installed in the cabinet type case 10 for transmitting information to plurality of terminal devices to provide service of various kinds, the terminal devices being connected by use of network with one another.

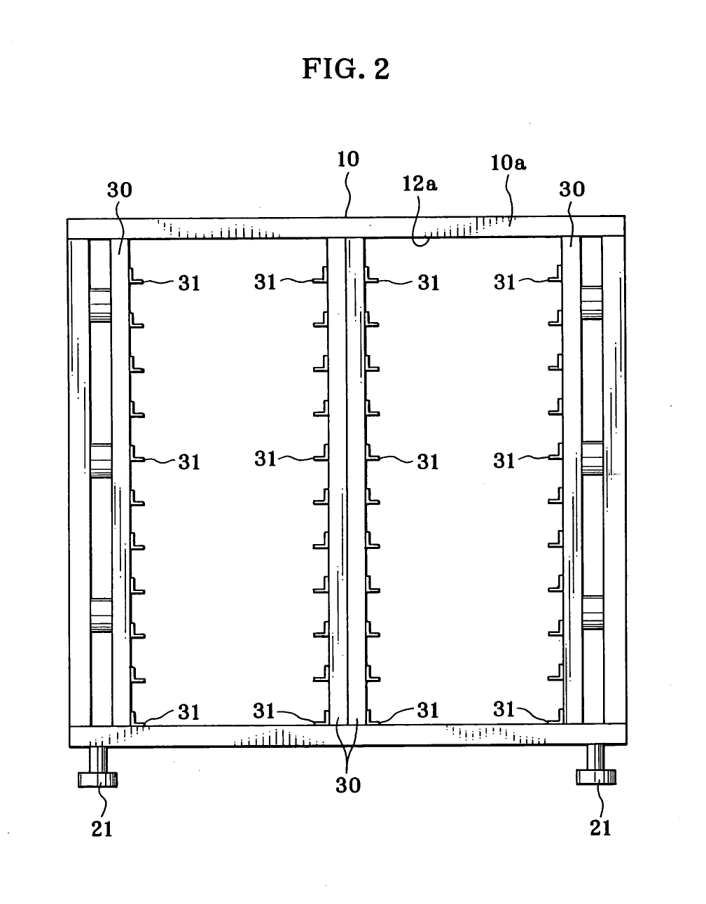

In FIG. 2, a plurality of rack frames 30 are arranged in the cabinet type case 10. 44 L shaped support rails 31 or guide supports as drawer tray supports are attached to the rack frames 30 for supporting the drawer trays 11 in a slidable manner. The support rails 31 are 22 pairs in association with the 22 drawer trays 11. The support rails 31 guide the drawer trays 11 being moved outwards and inwards relative to the cabinet type case 10 through the front face 10a. The support rails 31 are so structured that the drawer trays 11 are disposed over one another tightly with a minimized clearance. The server apparatus 2 is constructed in a compact shape owing to this arrangement of the drawer trays 11. Cooling with the fans 19 to be described later can be efficient.

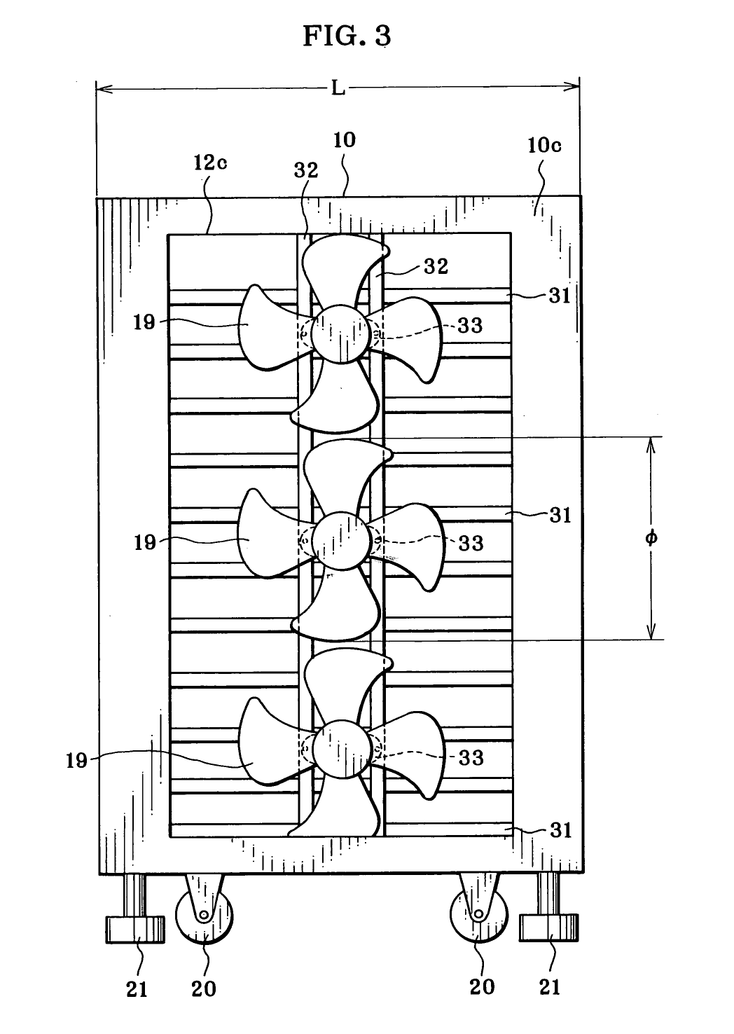

In FIG. 3, fan support frames 32 are disposed to extend on the side faces 10c of the cabinet type case 10 for installing the six fans 19. An intermediate panel 33 for support is fastened to the fan support frames 32 with screws, to retain the fans 19 on the fan support frames 32. The fans 19 are oriented to direct its front surface toward the side opening 12c. When the server components 42 of FIG. 4 are powered, the fans 19 start rotating to send cooling gas or air.

Let φ be an outer diameter of a blade portion of the six fans 19. Let L be a length of a shorter side line of the side faces 10c of the cabinet type case 10 where the fans 19 are attached. The fans 19 are structured so as to satisfy a condition
L/3≦φ<L

A typical example of the fans 19 is a general-purpose ventilation fan UL-30A (trade name) manufactured by Hitachi Home & Life Solution Co., Ltd. In this model, φ=30 cm.

In FIG. 4, each of the server components 42 or cluster nodes as circuit units is contained one of the drawer trays 11. Any one of the server components 42 is constructed by various elements including an electronic circuit board 40, and a storage device 41 or hard disk drive (HDD). The circuit board 40 has component devices or circuit elements, such as a power source device, central processing unit (CPU) and the like. Heat generating parts 40a, such as power source, are mounted in a relatively high density on the circuit board 40 in its portion close to the fans 19. The heat generating parts 40a include parts of a first group located on the left side and included in the left-side drawer tray stack, and a second group located on the right side and included in the right-side drawer tray stack.

On the drawer trays 11, the server components 42 are connected by a hub with one another. Various examples are included in the server components 42, such as a file server, a printing server, an electronic mail server and the like. The file server causes plural users operating terminal devices to use files commonly on their network. The printing server manages printers connected with the network. The electronic mail server executes operation of transmission and reception of electronic mails. Note that combinations of the server components 42 may be determined in any suitable manner for various purposes. For example, plural server components 42 of the same purposes can be combined, and can operate under a controlled condition.

Each of the drawer trays 11 includes side panels 43, a rear panel 44 or rear edge, a lower panel 45 and a front panel 49. The lower panel 45 supports the server components 42 secured thereto. A light source 47 or lamp and an interface access opening 48 for insertion are disposed in the front panel 49 as well as the power source pushbutton 46. The light source 47 is an indicator for informing information. The interface access opening 48 is formed for access from the outside for connection. Recesses 50 are formed in the side panels 43 and the rear panel 44. The recesses 50 define a path of a flow of cooling air from the fans 19 directly toward the server components 42. The drawer trays 11 have portions of the side panels 43 and the lower panel 45 supported in the support rails 31, and are movable between a protrusion state position and a contained state position through the front face 10a of the cabinet type case 10.

Note that one purpose to slide out each of the drawer trays 11 is to repair the server components 42 in breakage, or to maintain the server components 42.

In operation, the server apparatus 2 is supplied with power, and the power source pushbutton 46 is depressed at each of the drawer trays 11. Then one of the server components 42 or cluster nodes as circuit units starts operation. The six fans 19 are supplied with power in a manner separate from powering of the server components 42, and starts blowing. External air is caused through the inlets 18 of the side cover panels 15 to flow into the cabinet type case 10, and is blown to the server components 42 inside the drawer trays 11. The cooling air is heat exchange medium, which dissipates heat generated by the server components 42. The heat generating parts 40a receive the cooling air in a concentrated manner, and cooled particularly by the fans 19 as portions of the circuit board 40 with circuit elements mounted with high density. After the cooling of the server components 42, the cooling air is vented to the outside of the cabinet type case 10 through the vents 16 and 17 in the front and rear cover panels 13 and 14.

As the recesses 50 are formed in the side panels 43 and the rear panel 44, air in the drawer trays 11 can be vented efficiently. Manual handling in the course of maintenance of the server apparatus 2 can be facilitated and quickened. Also, the use of the support rails 31 can keep small the clearance between the drawer trays 11. Only with the six fans 19, the 22 server components 42 can be cooled with high efficiency. Performance of the fans 19 can be fully utilized. Also, each one of the server components 42 is incorporated in the drawer trays 11, the server components 42 being operable for common operation. The fans 19 are disposed and oriented in a direction crosswise to the outward and inward movement of the drawer trays 11. Thus, the server apparatus 2 can be inspected or maintained with great ease.

Furthermore, the fans 19 have the large outer diameter effective in cooling quickly. It is possible to suppress noise of the fans 19 in operation down to a considerably low level, for example as small as 50 dB as measured at a distance of one (1) meter from the inlets 18 of the side cover panels 15. The electronic apparatus can be installed in a juxtaposed manner with a telefacsimile, copying machine and other electronic instruments in a room, without keeping a large space particular to installation of a widely used server.

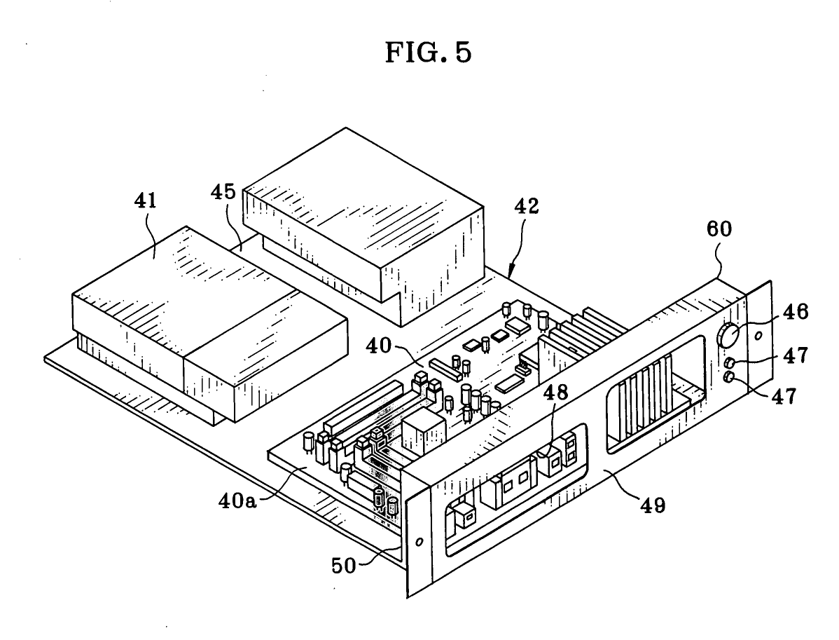

The position of the recesses 50 in the drawer trays 11 is not particularly limited. The recesses 50 can be positioned in a portion of the drawer trays 11 opposed to the six fans 19, for example the side panels 43 on the side of the fans 19. In FIG. 5, another preferred embodiment is illustrated, in which sliding drawer trays 60 in a multi tier form do not have the side panels 43 and the rear panel 44. The drawer trays 60 are constituted by respectively the lower panel 45 and the front panel 49. This can reduce the manufacturing cost to a considerable extent.

Note that, regarding the rear face 10b and the rear opening 12b, the rear cover panel 14 may have a size fully extending without the rear opening 12b. Also, the rear cover panel 14 may be attached unremovably to the rear face 10b in the rear of the cabinet type case 10.

In the present embodiment, the electronic apparatus is the server. However, an electronic apparatus of the invention may be any suitable device, for example, storage device, router, amplifier, power source device, measuring device, communication interface and the like.

Although the present invention has been fully described by way of the preferred embodiments thereof with reference to the accompanying drawings, various changes and modifications will be apparent to those having skill in this field. Therefore, unless otherwise these changes and modifications depart from the scope of the present invention, they should be construed as included therein.

What is claimed is:

1. An electronic apparatus having plural circuit units, comprising:
a cabinet type apparatus case, having plural openings and plural outer cover panels, wherein said plural openings are formed in respectively at least a front face and first and second side faces thereof, and said outer cover panels close said plural openings;
plural sliding drawer trays, arranged in a multi tier form, contained in said cabinet type case, movable in and out through a front opening included in said openings, wherein each of said drawer trays has a lower panel and a peripheral panel, each of said circuit units is secured to said lower panel, and contained therein;
a vent, formed in at least one of said outer cover panels, for air discharge;
an inlet, formed in a cover panel of said outer cover panels different from said vent, for intake of external air for cooling;
at least one first to fourth fans for flowing in of air through said inlet, for blowing said air to said circuit units, and for venting said air through said vent, to cool said circuit units;
wherein said first and second fans are disposed on respectively said first and second side faces, and said third and fourth fans are disposed higher than said first and second fans respectively at a predetermined distance;
at least one recess, formed in said drawer trays, opposed to at least one of said first to fourth fans.

2. An electronic apparatus as defined in claim 1, wherein said vent is formed in each of said front face and a rear face of said cabinet type case;
said inlet is formed in each of said first and second side faces;
said at least first to fourth fans are disposed between said first or second side face and said drawer trays.

3. An electronic apparatus as defined in claim 1, wherein each of said circuit units includes a heat generating part mounted in a concentrated manner, and located close to one of said first to fourth fans.

4. An electronic apparatus as defined in claim 3, wherein said recess is formed in said peripheral panel.

5. An electronic apparatus as defined in claim 4, wherein said recess is formed in a portion of said peripheral panel positioned on one of said first and second side faces and a rear face of said cabinet type case.

6. An electronic apparatus as defined in claim 5, wherein said outer cover panels include:
a front cover panel, disposed on said front face, for closing one of said openings;
a rear cover panel, disposed on a rear face of said cabinet type case, for closing one of said openings; and
first and second side cover panels, disposed on respectively said first and second side faces, for closing openings among said openings.

7. An electronic apparatus as defined in claim 5, wherein said cabinet type case and said first to fourth fans satisfy a condition of
L/3≦φ<L
where φ is an outer diameter of said first to fourth fans;
L is a length of a shorter side line of said side faces.

8. An electronic apparatus as defined in claim 5, wherein said plural drawer trays are constituted by first and second drawer tray stacks, and said second drawer tray stack is disposed beside said first drawer tray stack;
further comprising plural guide supports, disposed on an inside of said cabinet type case, for guiding plural drawer trays movable in and out.

9. An electronic apparatus as defined in claim 3, wherein said vent is constituted by:
a first group of vents disposed in a rear face of said cabinet type case; and
a second group of vents, disposed in said front face, and having a total area of openness larger than a total area of openness of said first group of said vents.

10. An electronic apparatus as defined in claim 3, wherein said circuit units are server components.

11. An electronic apparatus as defined in claim 3, wherein said at least first to fourth fans are at least first to sixth fans, and said fifth and sixth fans are disposed higher than said third and fourth fans respectively at a predetermined distance.
